(19) United States
(12) Patent Application Publication
(10) Pub. No.: US 2026/0293042 A1
(43) Pub. Date: Sep. 24, 2026

(54) COOLING BLOCK WITH COMPLEX FLOW MANIFOLDING

(71) Applicant: HRL Laboratories, LLC, Malibu, CA (US)

(72) Inventors: Christopher Roper, Thousand Oaks, CA (US); Jeremy Orosco, Canoga Park, CA (US)

(21) Appl. No.: 19/333,036

(22) Filed: Sep. 18, 2025

Related U.S. Application Data
(60) Provisional application No. 63/775,919, filed on Mar. 21, 2025.
(60) Provisional application No. 63/775,924, filed on Mar. 21, 2025.

(51) Int. Cl. H05K 7/20

(52) U.S. Cl. CPC H05K 7/20254; H05K 7/20272; H05K 7/20281; H05K 7/20927

(57) ABSTRACT

A cooling block including a flow manifold and a finned plate having a base plate and a microchannel array, and a cooling system including the cooling block are provided. The flow manifold is fabricated utilizing additive manufacturing and include a symmetric multiscale hierarchical flow routing structure designed and/or is fabricated with injection molding or configurable segmented sheet metal and includes a multiscale hierarchical flow routing structure designed to reduce or minimize or reduce pressure drop and thermal resistance. The flow manifold incudes a first level including first fluid passages open to an inlet, an output level including second fluid passages open to an outlet, and a second level including first fluid passages and second fluid passages. The cooling system further includes at least one pump and at least one heat exchanger in fluid communication with the flow manifold of the cooling block.

### CROSS-REFERENCE TO RELATED APPLICATIONS

This application claims priority to and the benefit of U.S. Provisional Application Nos. 63/775,919 and 63/775,924, each filed on Mar. 21, 2025 in the United States Patent and Trademark Office, the entire contents of each of which are incorporated herein by reference.

### BACKGROUND

### 1. Field

One or more aspects of embodiments of the present disclosure relate to cooling systems for high-heat flux devices, specifically focusing on configurable segmented cold plates with complex flow manifolding.

### 2. Description of Related Art

Existing cooling solutions are limited by high manufacturing costs and complex geometries that are difficult to produce. The present disclosure improves upon these limitations by enabling injection molded and configurable segmented cooling block with a finned plate and complex flow manifold configurations. The benefits of microchannel cooling have been described previously, and manifolded microchannel designs are suitable to reduce pressure drop.

The following references are further provided and the entire contents of each of which are incorporated herein by reference:
D. B. Tuckerman and R. F. W. Pease, IEEE Electronic Device Letters, vol. EDL-2, no. 5, pp. 126-129 (1981).
M. A. Arie, et al., International Journal of Heat and Mass Transfer, vol. 81, pp. 478-489 (2015).

The present disclosure is related to U.S. Pat. No. 11,680,756 issued to HRL and U.S. Patent Publication No. 2025/0071936 and the entire content of each of which is hereby incorporated by reference.

The preceding information disclosed in this Background section is only for enhancement of understanding of the background and related art of the disclosure and therefore it may contain information that does not constitute prior art.

### SUMMARY

The present disclosure is directed toward a cooling block including a flow manifold with complex flow distribution manifolding. More specifically, the flow manifold includes hierarchically interleaved multiscale flow manifolding (HIMFM) and may be injection molded or produced from configurable segmented material (e.g., sheet metal). The present disclosure enables manufacturing of the HIMFM that was first disclosed in U.S. Pat. No. 11,680,756 for use in countercurrent heat exchangers, where heat exchange across prescribed portions of the manifolding walls is desirable. The HIMFM geometry is dependent on costly additive manufacturing methods due to the complex geometries involved. The present disclosure describes methods for manufacturing a liquid-cooling heat sink with HIMFM using layer-by-layer manifold fabrication and injection molding fabrication.

Aspects of embodiments of the present disclosure are directed toward innovative cooling solutions for electronic devices. The disclosure enables injection molded and configurable segmented manufacturing of HIMFM thus simplifying construction and lowering costs to manufacturing these geometries while preserving the performance and/or efficiency benefits they provide.

The disclosure further enables modular integration into scalable thermal management systems, including those used in AI data centers, aerospace platforms, and/or high-power photonics. The complex distribution flow manifold design ensures substantially uniform coolant distribution, which is desired or suitable or even critical for minimizing or reducing thermal gradients and enhancing device reliability.

Additional aspects will be set forth in part in the description which follows and, in part, will be apparent from the description, or may be learned by practice of the presented embodiments of the disclosure.

One or more aspects of embodiments of the present disclosure are directed toward a cooling block including: a finned plate including a base plate and a microchannel array; and a flow manifold having stacked layers and including: a first fluid passage open to an inlet and a second fluid passage open to an outlet in a first level of the flow manifold; and first fluid passages and second fluid passages in a second level of the flow manifold, each of the first fluid passages in the second level is in fluid communication with the inlet via the first fluid passage in first level, and each of the second fluid passages in the second level is in fluid communication with the outlet via the second fluid passage in the first level.

In one or more embodiments, the stacked layers may include layers of an injection molded material including polymers, resins, metals, and combinations thereof.

In one or more embodiments, the layers may include curvilinear transition layer unit cells.

In one or more embodiments, the curvilinear transition layer unit cells may include a draft angle.

In one or more embodiments, the stacked layers may include layers of sheets.

In one or more embodiments, the sheets may include first metal sheets having a first set of physical properties and second metal sheets having a second set of physical properties.

In one or more embodiments, the flow manifold may include at least one inlet/outlet layer, at least one discretization layer, and at least one crossflow layer.

In one or more embodiments, the flow manifold may include at least one recessed layer

In one or more embodiments, the flow manifold may include a microchannel layer and a baseplate layer.

In one or more embodiments, the first fluid passages in the second level may be greater in number than the first fluid passages in the first level, the first fluid passages in the first level extend in a first direction, the first fluid passages in the second level extend in a second direction, the second direction perpendicular to and crossing the first direction, each of the first fluid passages in the second level extend under the first fluid passages in the first level.

In one or more embodiments, the first fluid passages in the second level may be interleaved with the second fluid passages in the second level.

In one or more embodiments, the microchannel array may include a plurality of fins, the fins being connected to and extending from a surface of the base plate, adjacent ones of the fins being spaced apart from each other to form a plurality of microchannels between the fins, one of the microchannels being between each adjacent two of the fins, and wherein an interior of the flow manifold is in fluid communication with the microchannels.

In one or more embodiments, the microchannels extend in a direction parallel to each other and perpendicular to a direction of extension of a plurality of first fluid passages in a lowest level of the flow manifold.

In one or more embodiments, a width of the microchannels may be about 1 micrometer (μm) to about 1000 μm.

In one or more embodiments, the fins may include a thermally conductive material and have a highest thermal conductivity axis with a conductivity of at least about 50 watt per meter degree K (W/m-K), a thickness of the fins may be about 1 μm to about 200 μm, and a height of the fins may be about 200 μm to about 3000 μm.

In one or more embodiments, the base plate may include aluminum, carbon, copper, gold, molybdenum, nitrogen, palladium, platinum, silicon, silver, tungsten, graphite, diamond, an alloy thereof, a compound thereof, and any suitable combination thereof, a thickness of the base plate may be about 10 μm to about 5000 μm, and a shear modulus of the base plate may be about 10 megapascal (MPa) to about 300 gigapascal (GPa).

In one or more embodiments, the flow manifold may include a thermal isolation layer between the inlet and the outlet, the thermal isolation layer may include a gas-filled cavity, an aerogel, or a low-conductivity polymer.

One or more aspects of embodiments of the present disclosure are directed toward a cooling system including: an electronic component; a cooling block according to the present disclosure on the electronic component; and a heat exchanger in fluid communication with the flow manifold of the cooling block.

One or more aspects of embodiments of the present disclosure are directed toward a cooling system including: a plurality of cooling blocks as described herein; a shared coolant distributor configured to supply a coolant to each of the plurality of cooling blocks; a controller configured to monitor and adjust coolant flow rates to each of the plurality of cooling blocks based on thermal load; and a heat exchanger in fluid communication with the shared coolant distributor.

One or more aspects of embodiments of the present disclosure are directed toward a method including: forming a flow manifold by stacking a plurality of layers; providing a finned plate including a microchannel array; coupling the flow manifold and the finned plate, wherein, an interior of the flow manifold is in fluid communication with the microchannel array, and the method is a method of manufacturing a cooling block.

In one or more embodiments, the forming of the flow manifold may include stacking a plurality of layers of an injection molded material, stacking a plurality of layers of sheets, or combinations thereof.

In one or more embodiments, a cooling block includes a finned plate including a base plate and a microchannel array, and a flow manifold constructed from stacked layers and including a first level having first fluid passages open to an inlet, an output level having second fluid passages open to an outlet, and a second level including first and second fluid passages. The cooling block may be fabricated by a method including manufacturing the flow manifold and the finned plate as a single integrated structure, and post-processing the internal flow passages to improve surface finish and flow uniformity.

This integrated fabrication approach enables precise alignment of the manifold and microchannel features, reduces interfacial thermal resistance, and supports complex geometries that enhance thermal and hydraulic performance.

### BRIEF DESCRIPTION OF THE DRAWINGS

The patent or application file contains at least one drawing executed in color. Copies of this patent or patent application publication with color drawings will be provided by the Office upon request and payment of the necessary fee.

The features and advantages of embodiments of the present disclosure will be better understood by reference to the following detailed description if (e.g., when) considered in conjunction with the accompanying drawings.

FIG. 1 is a schematic perspective view of a cooling block according to one or more embodiments of the present disclosure.

FIG. 2 is a schematic diagram of the stacked layers of a flow manifold according to one or more embodiments of the present disclosure.

FIGS. 3A-3B are cut-away perspective views of a flow manifold according to one or more embodiments of the present disclosure.

FIG. 4A is a schematic view of a finned plate according to one or more embodiments of the present disclosure.

FIG. 4B is an expanded view of FIG. 4A.

FIG. 5 is a perspective view of a flow manifold having a first level that includes tubular extrusion that may be the cool fluid inlet and tubular extrusion that may be the warm fluid outlet.

FIG. 6A shows the flow direction in fluid passages of a flow manifold and a microchannel array according to one or more embodiments of the present disclosure.

FIG. 6B is a cross-sectional view of a microchannel according to one or more embodiments of the present disclosure.

FIG. 7A is a perspective view of a curvilinear transition layer unit cell according to one or more embodiments of the present disclosure.

FIG. 7B is a perspective view of a hierarchical-level transition layer according to one or more embodiments of the present disclosure.

FIG. 7C is a perspective view of a curvilinear transition layer unit cell having a draft angle according to one or more embodiments of the present disclosure.

FIG. 7D is a perspective view of a longitudinally bisected curvilinear transition layer unit cell according to one or more embodiments of the present disclosure.

FIGS. 8-10 are charts of performance evaluations of a cooling block according to the present disclosure.

### DETAILED DESCRIPTION

The following description sets forth one or more suitable example embodiments and details in order to provide a more thorough understanding of the present disclosure. However, the subject matter of the present disclosure may be embodied in many different forms, and is not limited to the embodiments and details set forth herein. All disclosed features may be replaced with comparable features serving the same, equivalent, or similar purpose, unless expressly stated otherwise. Features of one or more embodiments may be incorporated into other embodiments unless expressly stated otherwise.

In the drawings, the same or similar reference numerals refer to the same or similar elements throughout, and duplicative descriptions thereof may not be provided. The drawings are not necessarily drawn to scale, and thicknesses and dimensions of elements may be exaggerated for clarity.

Unless otherwise defined, all chemical names, technical and scientific terms, and terms defined in common dictionaries should be interpreted as having meanings consistent with the context of the related art and should not be interpreted in an ideal or overly formal sense.

As utilized herein, expressions such as “at least one of,” “one of,” “at least one selected from among,” and “selected from among,” if (e.g., when) preceding a list of elements, modify the entire list of elements and do not modify the individual elements of the list. As utilized herein, the expressions “at least one of A, B, or C”, “one of A, B, C, or a combination thereof” and “one of A, B, C, and a combination thereof” refer to each component and a combination thereof (e.g., A; B; A and B; A and C; B and C; or A, B, and C). For example, “at least one of a to c,” “at least one of a, b or c,” and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As utilized herein, it is to be understood that the terms such as “including,” “includes,” “include,” “having,” “has,” “have,” “comprises,” “comprise,” and/or “comprising” are intended to indicate the existence of the features, numbers, steps, actions, components, parts, ingredients, materials, and/or one or more (e.g., any suitable) combinations thereof disclosed in the specification and are not intended to preclude the possibility that one or more other features, numbers, steps, actions, components, parts, ingredients, materials, and/or one or more (e.g., any suitable) combinations thereof may exist or may be added. The term “combination thereof may include a mixture, a laminate, a complex, a copolymer, an alloy, a blend, a reactant of constituents.

As utilized herein, singular forms such as “a,” “an,” and “the” are intended to include the plural forms as well, unless the context clearly indicates otherwise.

As utilized herein, the terms “use,” “using,” and “used” may be considered synonymous with the terms “utilize/utilization,” “utilizing,” and “utilized,” respectively.

In this context, “consisting essentially of” refers to that any additional components will not materially affect the chemical, physical, optical or electrical properties of the semiconductor film.

Furthermore, any claim element that does not explicitly recite a “means for” or “step for” in performing a function, is not to be interpreted as a “means” or “step” clause under 35 U.S.C. § 112 (f). The use of “step of” or “act of” in the claims herein is not intended to invoke the provisions of 35 U.S.C. § 112 (f).

It will be understood that if (e.g., when) an element (e.g., layer) is referred to as being “outside,” “inside,” “on,” “above,” “below,” “connected to,” or “coupled to” another element, it may be in direct contact with the other element, or one or more intervening elements may be present. In contrast, if (e.g., when) an element (e.g., layer) is referred to as being “directly” on, above, below, and/or the like. another element, no intervening elements are present. Terms describing spatial relationships between elements or features (such as “below,” “lower,” “under,” “above,” “upper,” and/or the like.) should be interpreted in the context of the device as a whole. For example, an element described as being “under” a second element could be alternatively described as being “above” the second element in an alternative orientation, if (e.g., when) such orientation is available.

Example embodiments of the present disclosure will be described with reference to the accompanying drawings. In the drawings, the same or similar reference numerals refer to the same or similar elements throughout, and duplicative descriptions thereof may not be provided the specification. The thickness of layers, films, panels, regions, and/or the like, are exaggerated for clarity. It will be understood that if (e.g., when) an element such as a layer, film, region, or substrate is referred to as being “on” another element, it can be directly on the other element or intervening element(s) may also be present. In contrast, if (e.g., when) an element is referred to as being “directly on” another element, there are no intervening elements present.

Herein, the use of the term “may,” if (e.g., when) describing embodiments of the present disclosure, refers to “one or more embodiments of the present disclosure.” In addition, the use of alternative language, such as “or,” if (e.g., when) describing embodiments of the present disclosure, refers to “one or more embodiments of the present disclosure” for each corresponding item listed. For example, “A or B” is construed to include A, B, A+B, and/or the like. Similarly, the term “and/or” includes any and all combinations of one or more of the associated listed items. The symbol “/” as utilized herein, may be interpreted as “and” or “or” according to the context. Also, the term “exemplary”, “preferred”, “preferable”, “preferably”, and/or the like is intended to refer to an example, embodiment, or illustration.

All references herein to the/our “invention”, “invented idea”, “our system”, “this system” (in context with “our system”), “proposed system”, “innovative method”, “inventive concept”, “method”, “this circuit”, “this architecture”, “this”, “the current invention”, and/or the like shall refer to one or more embodiments of present disclosure.

### INTRODUCTION

The present disclosure provides a flow manifold having multiscale hierarchically interleaved flow routing like that described for heat exchangers in U.S. Pat. No. 11,680,756 and U.S. Patent Publication No. 2025/0071936, with the important innovation of injection molding and configurable segmented processes that simplify construction and lower costs of manufacturing. The novelties in this design are physics-based design optimizations including thermal conductivity dependent fin heights, optimal or enhanced short-throw recirculation paths, and insulating materials selection for manifold fabrication (e.g., high-temperature acrylate resin).

This present disclosure relies on deep understanding of the HIMFM technology and the nature of how the complex geometries contribute to performance and efficiency benefits beyond other flow routing and cold plate technologies. Without this understanding, both in terms of theory and in terms of practice (e.g., laboratory-based testing and iterative development), it is a counterintuitive idea that complex curvilinear geometries can be coarsely approximated as described herein, and provide significant performance and efficiency benefits. For example, the cooling block of the present disclosure may be particularly useful for thermal management of electric vehicle traction inverter power modules, where power MOSFET or IGBT switching devices dissipate large amounts of heat in small areas.

In terms of efficiency, an optimal or desired design performs provides minimal or reduced amount of desired or required power input. Pressure drop is directly associated with this input power, and thus minimizing or reducing or reducing pressure drop is desirable.

In terms of performance, a reduced specific thermal resistance (i.e., inverse total heat transfer coefficient) enables the removal of large heat loads (typically in this case, multiple kilowatts) without a large rise in temperature across the heat transfer interface, and over relatively small areas (typically in this case, one kilowatt dissipated over less than three square centimeters). The thermal resistance of a single-phase liquid cold plate includes thermal resistance of solid conduction, thermal resistance of convection, thermal resistance of sensible heat gain, and/or thermal resistance of a thermal interface material.

This invention applies to any application where thermal management of high heat load (multiple kilowatts) and/or high heat flux (hundreds of watts per square centimeter) producing devices is desired or required under significant size, weight, and/or efficiency constraints. Commercial applications include but are not necessarily limited to: power electronics (power transistors, amplifiers, and/or the like.), densely populated ICs used for computational tasks (CPUs and GPUs, in particular those used in AI datacenters), communications systems (radar, microwave, 5G, and/or the like.), and high power laser applications (LIDAR), directed energy microwave systems, particle accelerator components (especially targets), aerothermal heating in high speed flight, and fusion reactor walls and blankets.

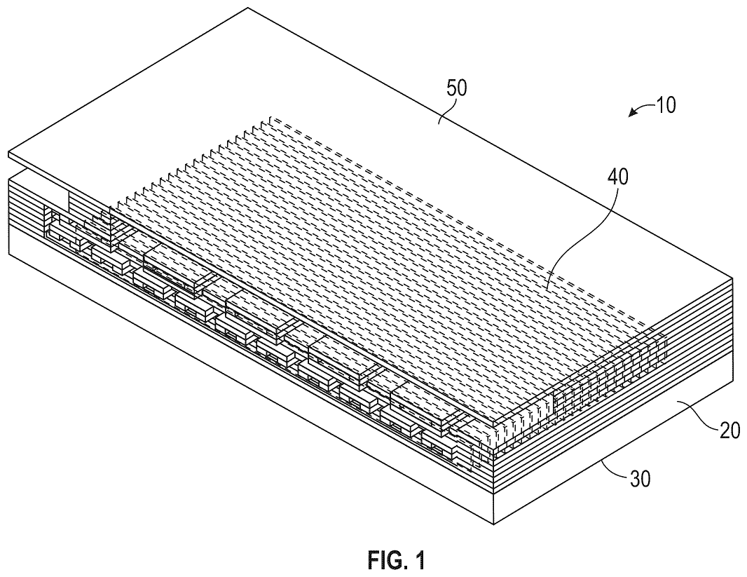

FIG. 1 shows a cooling block 10 including a finned plate 20 and a flow manifold 50. The finned plate 20 includes a base plate 30 and a microchannel array 40, and the finned plate 20 is coupled to the flow manifold 50 as described in more detail herein.

### Flow Manifold

According to one or more embodiments of the present disclosure, the flow manifold 50 includes stacked layers and includes the hierarchical-level transitions of multilevel hierarchically interleaved flow routing. The stacked layers may include flat sheets or curvilinear transition layer unit (CTLU) cells.

In one or more embodiments, a hierarchical-level transition may be injection molded and may be formed from an array of mirrored CTLU cells that may include an extrusion draft angle to provide suitable processing of the injection molded hierarchical-level transition. In some embodiments, the draft angle may be about 2 degrees (9) to about 10° from the vertical, but the present disclosure is not limited thereto. For example, a draft angle of about 1.5° to about 2° may be used for stacked layers of polymers, and of about 0.5° to about 1° may be used for stacked layers of metals. The size of the draft angle may be determined by the extrusion aspect ratio. An array of mirrored CTLU cells may include at least one lateral wall on the CTLU cells and/or at least one portioning layer unit cell (e.g., at a midpoint of the array) to provide a hierarchical-level transition having manifold envelope walls. A manifold envelope convex-type (kind) top layer may be created by standard injection molding methods.

In one or more embodiments, the stacked layers may include layers of an injection molded material such as polymers, resins, ceramics, glasses, composites, and/or a (e.g., any suitable) combination thereof, but the present disclosure is not limited thereto. In one or more embodiments, the stacked layers may include layers of sheets, (e.g., prefabricated sheets) which may include polymers, resins, ceramics, glasses, composites, and/or a (e.g., any suitable) combination thereof, but the present disclosure is not limited thereto. For example, the stacked layers may include a low-thermal conductivity, high-temperature resin (e.g., with heat deflection temperature specification determined by application temperature boundary conditions to thermally isolate the cold inflow from the hot inflow (prevents preheating and preserves maximal temperature difference)).

The stacked layers may include first layers having a first set of physical properties and second layers having a second set of physical properties. For example, two adjacent stacked layers may be one first layer having a first set of physical properties and one second layer having a second set of physical properties. In some embodiments, the stacked layers may include layers having substantially the same physical properties. For example, the stacked layers may include materials that are thermally insulating, thermally conducting, adhering, damping, sealing, and/or the like.

In one or more embodiments, the stacked layers may include layers of metal sheets. For example, the stacked layers may include first metal sheets having a first set of physical properties and second metal sheets having a second set of physical properties. For example, two adjacent stacked metals sheets may include one first metal sheet and one second metal sheet.

The stacked layers may include layers having substantially the same gauge or different gauges, and the gauge(s) may be chosen based on target feature size (e.g., height) of the hierarchical-level transitions.

In one or more embodiments, the stacked layers may include layers of metal sheets and the metal sheets may be punched. For example, the metal sheets may be punched to establish hierarchical structure (e.g., holes, slots, general regions) and/or the punching may create holes into a flat sheet. In some embodiments, the punching may occur in one or more steps and may draw or deep draw the sheet to provide a 3-dimensional shape with taller lateral flow passages in a single layer. The metal sheets may be punched and bent to establish hierarchical structure and reduce sharp corners (e.g., reduce pressure drop).

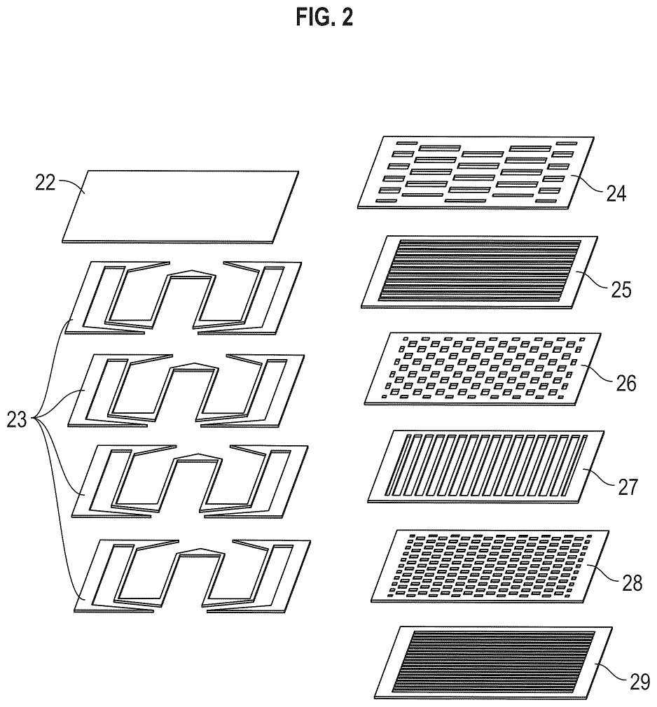

FIG. 2 shows an example arrangement of stacked layers included in a flow manifold according to one or more embodiments of the present disclosure. The assembly order of the flow manifold shown in FIG. 2 includes cover layer 22 followed by inlet/outlet layers 23, which may be followed by a first discretization layer 24, a first crossflow layer 25, a second discretization layer 26, a second crossflow layer 27, a third discretization layer 28, and a third crossflow layer 29. The example arrangement of stacked layers shown in FIG. 2 includes four inlet/outlet layers 23, but the present disclosure is not limited thereto and the number of inlet/outlet layers 23 may be adjusted to accommodate flow rate as needed.

In one or more embodiments, each layer in the stacked manifold serves a distinct functional role in enabling hierarchical flow distribution. The inlet/outlet layers (23) provide primary access points for coolant to enter and exit the flow manifold. The discretization layers (24, 26, 28) progressively divide, or collect, flow into smaller, or larger, channels, enabling multiscale flow partitioning. The crossflow layers (25, 27, 29) redirect flow laterally across the flow manifold, facilitating interleaving of cool and warm fluid paths and enhancing thermal isolation. This alternating structure of discretization and crossflow layers may provide arbitrary (e.g., non-hierarchical) complex 3D flow structures and hierarchical interleaved flow routing architectures, which minimize or reduce pressure drop and enhance or improve uniform coolant distribution across the microchannel array.

In one or more embodiments, following the third crossflow layer 29 may be at least one recessed layer which is an open frame that allows the inlet and outlet of the final (lowest) hierarchical level of the flow manifold to access the microchannel array, as described in more detail herein. The at least one recessed layer(s) may be stacked on the finned plate and are used in a number needed to accommodate the height of the fins of the microchannel array, as described in more detail herein.

In one or more embodiments, following the third crossflow layer 29 may be a microchannel layer followed by a baseplate layer. The microchannel layer includes the microchannels of the microchannel array and is arranged orthogonal to the direction of the inlet and outlet of the final (lowest) hierarchical level of the flow manifold.

The stacked layers may be coupled or bonded to each other in one or more suitable ways including for polymers the use of adhesive, ultrasonic welding, laser welding, heat staking, and/or the like, and for metals the use of brazing, solder, adhesive, ultrasonic welding, laser welding, thermite welding, and/or the like, but the present disclosure is not limited thereto.

The stacked layers of sheet-style layers may not be bonded and may be coupled by being stacked inside an appropriately or suitably sized envelope and then compressed with screw attachment to the finned plate and heat source. In one or more embodiments, sheet-style layers may be stacked with aligned screw holes (e.g., at corners), and then all compressed together with screw attachment to the finned plate and heat source or may be stacked with aligned clearance holes for insertion of alignment pins/dowels, and then compressed with top surface mounting plate that is screwed through the finned plate onto the heat source.

In one or more embodiments, the stacked layers of sheet-style layers may be compressed via screw and nut, e.g., with clearance holes at corners disconnected from fluid regions, and screw the stacked layers together onto heat source. The sheet style layers may be compressed via top surface mounting plate, where stacked layers are aligned via clearance holes at corners with pins/dowel inserts, plate with mounting holes place along top, and plate screwed onto the heat source compressing the stacked layers. The sheet style layers may be compressed via housing, stacked within conformal housing having screw holes in tabs.

The hierarchical-level transitions may include alignment (e.g., registration) features to assist alignment of hierarchical-level transitions above and/or below, e.g., pins in one hierarchical-level transitions and mating blind holes in an adjacent hierarchical-level transition, or grooves in one hierarchical-level transitions and mating ridges in an adjacent hierarchical-level transition.

Without wishing to be limited by theory, thermal communication between the stacked layers may not be critical, e.g., due to preference for low thermal conductivity of the flow manifold to prevent or reduce thermal crosstalk between inflow and outflow. In some embodiments, limited thermal coupling is tolerable as long as sufficient hermeticity is provided. For example, in a cooling block using a single working fluid limited amounts of thermal crosstalk may be tolerable depending on application constraints. Whereas thermal crosstalk would generally not be tolerable in a heat exchanger including two distinct working fluids.

The hierarchical-level transitions may include negative space features drafted according to injection molding type (kind).

The flow manifold may include at least one single walled region of the thermally insulative material or at least one double walled region of the thermally conductive material.

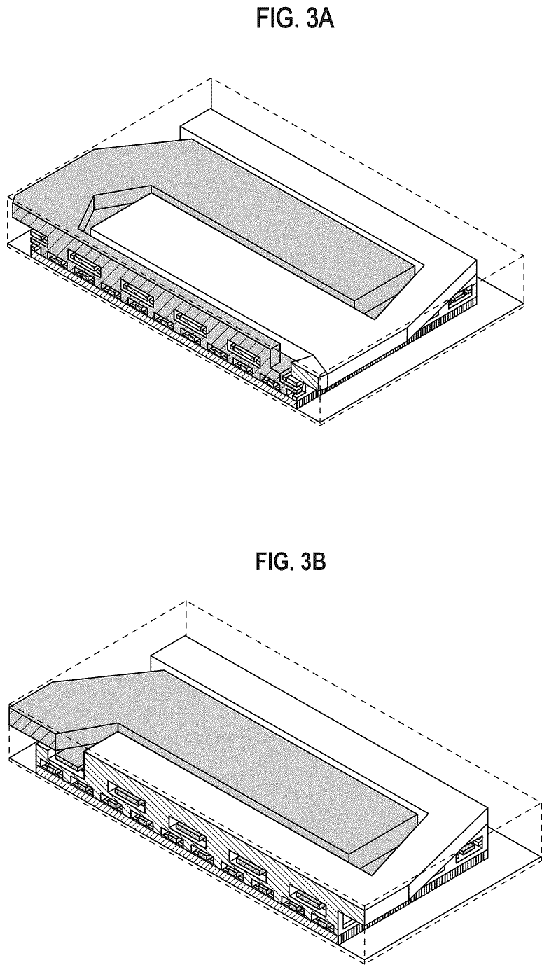

FIGS. 3A and 3B are cut-away perspective views of the flow manifold 50 showing a cross-sectional profile of a cool inflow region in blue, a warm outflow region in red, and three hierarchical-level transition layers. FIG. 3B illustrates the spatial separation of a cool incoming coolant passing through the blue inflow region and a warm outgoing coolant passing through the red outflow region across hierarchical transition layers. This configuration supports efficient thermal isolation and compact flow routing, which are important for minimizing or reducing thermal crosstalk and maintaining high thermal performance. Here, reference to “warm” and “cool” is only for ease of explanation, and terms can be replaced by “first” and “second” without affecting the disclosure. For example, the flow direction through flow manifold 50 may be reversed to provide substantially the same performance with the cool incoming coolant passing through the red region and the warm outgoing coolant passing through the blue region. In one or more embodiments, the flow manifold 50 includes a plurality of (at least one) cool fluid inlets and a plurality of (at least one) warm fluid outlets. Performance efficiency of the cooling block 10 and/or the flow manifold 50 may be improved by minimizing or reducing distances between inflow and outflow regions at an interface of and the finned plate 20, as described in more detail herein.

The flow manifold 50 may have single walls that are non-thermally conductive or may have double walls including two solid layers coupled only at the top and/or bottom and nowhere in between to provide a substantially continuous region of air separating the two layers. The single or double walls and the region of air are of minimum thickness as allowed by the manufacturing process. These strategies ensure that the distance traveled by a coolant in a fluid passage (e.g., between exiting the manifold as cold inflow and reentering the manifold as hot outflow) is a short flow path and is minimized or reduced to minimize or reduce pressure drop and improve heat transfer. Minimizing wall and gap thicknesses ensures short flow paths are as short as possible, which minimizes (reduces) frictional pressure loss and maximizes (increases) heat transfer due to maximization (increase) of developing regions. If (e.g., when) the double wall construction is used the flow manifold 50 may be manufactured from high thermal conductivity materials like metals, such that everywhere the cold inflow and hot outflow are oriented in adjacent cavities, the two are separated by a gap region with a gas state (e.g., air), for example cold inflow/metal manifold wall/air/metal manifold wall/hot outflow. Regions between the two walls may include air, an inert gas, a noble gas, aerogel, porous foam insulation, mechanical spacer features (e.g., periodic posts or spars), hollow microspheres (e.g. hollow glass microspheres), and/or a (e.g., any suitable) combination thereof. In some embodiments, the air gap (or gap region) may be filled with a low-conductivity gas such as xenon or krypton to further reduce thermal bridging. Alternatively, the gap may be evacuated to create a vacuum-insulated barrier.

In one or more embodiments, the flow manifold 50 includes a thermal isolation layer between the inlet and the outlet, and the thermal isolation layer may include a gas-filled cavity, an aerogel, or a low-conductivity polymer.

In one or more embodiments, the cooling block 10 includes at least one flow control element within the flow manifold 50 and the flow control element includes at least one valve, at least one variable orifice, and/or at least one deformable membrane configured to dynamically adjust flow distribution.

In one or more embodiments, flow dividers maybe also be provided and shaped to induce secondary flow structures that enhance convective heat transfer while maintaining laminar flow conditions.

### Finned Plate

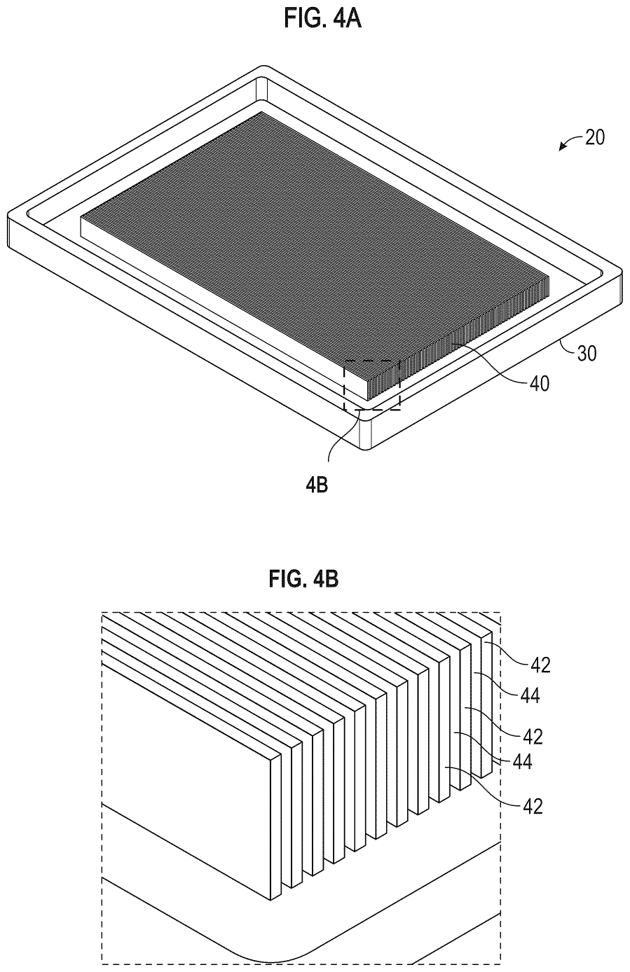

FIG. 4A shows the finned plate 20 of FIG. 1 in more detail. The finned plate 20 includes the base plate 30 and the microchannel array 40 including plurality of aligned microchannels 44 on the base plate 30. As explained in more detail, the base plate 30 is arranged on an electronic component to be cooled, and the flow manifold 50 receives coolant (e.g., from a secondary cooling loop) and discharges heated coolant to the same.

FIG. 4B is an expanded view of FIG. 4A showing a plurality of fins 42 included in microchannel array 40, the fins 42 being connected to and extending from a surface of the base plate 30, adjacent ones of the fins 42 being spaced apart from each other to form a plurality of microchannels 44 between the fins 42, one of the microchannels 44 being between each adjacent two of the fins 42. An interior of the flow manifold is in fluid communication with the microchannels 44. The microchannels 44 may extend in a direction parallel to each other and perpendicular to a direction of extension of a plurality of first fluid passages in a lowest level of the flow manifold 50. A second level, a third level, a fourth level, and/or the like may be the lowest level of the flow manifold 50, but the present disclosure is not limited thereto. In one or more embodiments, the lowest level of the flow manifold 50 may be a third level or a fourth level. Also, as shown in FIG. 4B, the fins 42 are spaced to form the microchannels 44, and may be composed of copper, graphite, and/or other high thermal conductivity materials.

In one or more embodiments, the finned plate 20, the base plate 30, and/or the microchannel array 40, may be manufactured by one or more suitable processes including skiving, micromachining, additive, and/or the like and then attached to the flow manifold by a bonding method such as screw compression, mounting plate, and/or the like, but the present disclosure is not limited thereto.

In one or more embodiments, portions of the finned plate 20, the base plate 30, the microchannel array 40, and/or the flow manifold 50 may be manufactured by a suitable additive manufacturing process (e.g., 3D printing). Some examples of the additive manufacturing process include vat polymerization (e.g., stereolithography; digital light processing; scan, spin, and selectively photocure; substantially continuous liquid interface production), powder bed fusion (e.g., selective laser sintering, direct metal laser sintering, selective laser melting, selective heat sintering, multi-jet fusion), binder jetting (e.g., 3DP, ExOne, VoxelJet, desktop metal), material jetting (e.g., Polyjet, Smooth Curvatures Printing, Multijet Modeling, Projet), sheet lamination (e.g., laminated object manufacture, selective deposition lamination, ultrasonic additive manufacturing), material extrusion (e.g., fused filament fabrication, fused deposition modeling, direct ink write), directed energy deposition (e.g., laser metal deposition, laser energy net shaping, direct metal depositions, laser engineered net shaping), hybrids of multiple additive manufacturing methods, and/or hybrids of additive and subtractive manufacturing methods. Subtractive manufacturing may refer to, as some examples, machining or computer numerical control (CNC) machining. In one or more embodiments, portions of the finned plate 20, the base plate 30, the microchannel array 40, and/or the flow manifold 50 may be fabricated utilizing a hybrid process combining laser powder bed fusion (LPBF) for structural features and electrochemical additive manufacturing (ECAM) for fine-resolution internal channels. This hybrid approach enables high-density microchannel integration with minimal post-processing.

One or more suitable post-processing treatments may be used to remove unwanted material after additive manufacturing and provide for a better interior surface finish, e.g., electrochemical etching, flushing with fluid and abrasive media, vibration, and/or a (e.g., any suitable) combination thereof. The manifold 50 and the finned plate 20 may be fabricated in two or more parts and then bonded or gasketed together as described in more detail herein. The manifold 50 and the finned plate 20 may be manufactured as a single piece using additive manufacturing (e.g. LBPF, SLS, ECAM, and/or the like.) methods to obtain single-piece construction.

In one or more embodiments, the flow manifold 50 and finned plate 20 are fabricated as a single integrated structure utilizing additive manufacturing. This integration reduces thermal interface resistance, improves mechanical alignment, and enables complex internal geometries that enhance thermal and hydraulic performance.

According to one or more embodiments, the flow manifold 50 and/or the finned plate 20 may be modular components and may be removably coupled or connected to each other.

The microchannel array 40, may be produced with arbitrary channel shapes and or protrusions or other features, e.g., used for boundary layer disruption and improved heat transfer in microchannel coldplates. The microchannel array 40, may be produced with sheet metal methods.

In one or more of embodiments, a width of the microchannels 40 is about 1 micrometer (μm) to about 1000 μm, about 5 μm to about 500 μm, or about 20 μm to about 200 μm. It is also understood that these ranges also include all sub-ranges and other ranges beginning and/or ending with any point within these ranges, for example, while the preceding range of about 20 μm to about 120 μm is disclosed, a range of, for example, about 40 μm to about 100 μm is also contemplated and included within the range.

The finned plate 20 may include about 50 to about 500 microchannels 44 that are in parallel alignment to one another.

The fins 42 include a thermally conductive material and may have a highest thermal conductivity axis with a conductivity of at least about 50 watt per meter degree K (W/m-K). Non-limiting examples of materials suitable for the fins 42 include aluminum, carbon, copper, gold, molybdenum, nitrogen, palladium, platinum, silicon, silver, tungsten, graphite, diamond, an alloy thereof, a compound thereof, and/or a (e.g., any suitable) combination thereof, such as CuW, Cu-diamond, Cu—SiC, Cu—AlN, but the present disclosure is not limited thereto. In one or more of embodiments, the fins may include aluminum having a thermal conductivity of about 200 W/m-K, silicon having a thermal conductivity of about 150 W/m-K, or copper having a thermal conductivity of about 400 W/m-K. In one or more of embodiments, the conductivity of the highest thermal conductivity axis of the fins 42 may be about 400 W/m-K to about 3000 W/m-K, about 600 W/m-K to about 1500 W/m-K, or about 800 W/m-K to about 1200 W/m-K. It is also understood that these ranges also include all sub-ranges and other ranges beginning and/or ending with any point within these ranges, for example, while the preceding range of about 800 W/m-K to about 1200 W/m-K is disclosed, a range of, for example, about 900 W/m-K to about 1000 W/m-K is also contemplated and included within the range.

Aligned graphite has a thermal conductivity in a range of about 1,000 W/m-K to about 1,500 W/m-K along a plane in which is its along-fin axis, compared with silicon, which has a thermal conductivity of about 100 W/m-K. Thus, aligned graphite enables higher fin efficiency (e.g., greater than about 50%) for high-aspect ratio fins (e.g., fins having a greater than 30:1 height to thickness ratio). In some embodiments, the fins 42 may include aligned pyrolytic graphite having a thermal conductivity greater than 1000 W/m-K along the fin axis.

In one or more of embodiments, a thickness of the fins 42 is about 1 μm to about 200 μm, about 5 μm to about 150 μm, or about 20 μm to about 120 μm. It is also understood that these ranges also include all sub-ranges and other ranges beginning and/or ending with any point within these ranges, for example, while the preceding range of about 20 μm to about 120 μm is disclosed, a range of, for example, about 40 μm to about 100 μm is also contemplated and included within the range.

In one or more of embodiments, a height of the fins may be about 200 μm to about 3000 μm, about 400 μm to about 2000 μm, or about 600 μm to about 1200 μm. It is also understood that these ranges also include all sub-ranges and other ranges beginning and/or ending with any point within these ranges, for example, while the preceding range of about 600 μm to about 1200 μm is disclosed, a range of, for example, about 900 μm to about 1000 μm is also contemplated and included within the range.

The base plate 30 has an optimum thickness to accommodate the stress caused if (e.g., when) connecting the finned plate 20 to the flow manifold 50. If (e.g., when) the base plate is too thin, the stresses may cause the microchannel arrays to bow and/or curve, which may increase thermal interface resistance between the finned plate and a heat source (e.g., an electronic component). If (e.g., when) the base plate is too thick, the added (unnecessary) material may increase the thermal resistance of solid conduction.

The base plate 30 may include thermal stress mitigating materials that have coefficient of thermal expansion (CTE) matching to the heat source material (e.g., a silicon electronic component) with relatively high compliance. For example, the CTE of CuMo and copper impregnated graphite are each similar to silicon. Non-limiting examples of materials suitable for the base plate include CuW, Cu-diamond, Cu—SiC, and Cu—AlN.

The base plate 30 may include aluminum, carbon, copper, gold, molybdenum, nitrogen, palladium, platinum, silicon, silver, tungsten, graphite, diamond, an alloy thereof, a compound thereof, and/or a (e.g., any suitable) combination thereof. The base plate 30 may be manufactured using skiving, related art machining (e.g., milling or sawing/cutting), or additive manufacturing (e.g., LBPF, SLS, ECAM, and/or the like.).

The fins 44 and the base plate 30 may be manufactured using the same method or the fins 44 may be fabricated onto a base plate that was previously fabricated using a different method (e.g., additive fins on a conventionally machined base plate). Additional machining may be performed on the finned plate 20 after the fins are formed (e.g., holes drilled, edges cut to shape).

In one or more of embodiments, a thickness of the base plate 30 may be about 10 μm to about 5000 μm, about 250 μm to about 2500 μm, or about 400 μm to about 600 μm. It is also understood that these ranges also include all sub-ranges and other ranges beginning and/or ending with any point within these ranges, for example, while the preceding range of about 250 μm to about 750 μm is disclosed, a range of, for example, about 300 μm to about 400 μm is also contemplated and included within the range.

In one or more of embodiments, a shear modulus of the base plate 30 may be about 10 megapascal (MPa) to about 300 gigapascal (GPa), about 100 MPa to about 100 GPa, or about 1000 MPa to about 5 GPa. It is also understood that these ranges also include all sub-ranges and other ranges beginning and/or ending with any point within these ranges, for example, while the preceding range of about 100 MPa to about 100 GPa, is disclosed, a range of, for example, about 800 MPa to about 80 GPa is also contemplated and included within the range.

### Hierarchical Interleaved Flow Routing

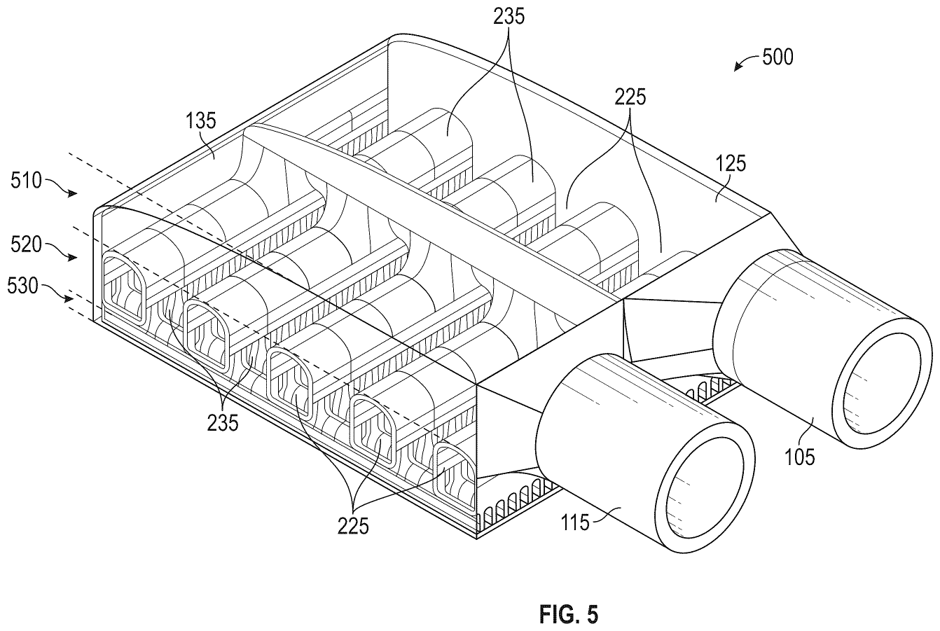

FIG. 5 shows a flow manifold 500 having a first level 510 that includes tubular extrusion 105 that may be the cool fluid inlet and tubular extrusion 115 that may be the warm fluid outlet, however the functions of extrusions 105/115 could be reversed. The first level 510 includes a first fluid passage 125 in fluid communication with the cool fluid inlet 105 and a second fluid passage 135 in fluid communication with the warm fluid outlet 115.

A second level 520 of flow manifold 500 has first fluid passages 225 and second fluid passages 235. Each of the first fluid passages 225 in fluid communication with the cool fluid inlet 105 via the first fluid passage 125, and each of the second fluid passages 235 in fluid communication with the warm fluid outlet 115 via the second fluid passage 135.

In one or more embodiments, the first fluid passages 225 in the second level 520 may be greater in number than the first fluid passage 125 in the first level 510.

In one or more embodiments, the first fluid passage 125 in the first level may extend in a first direction. The first fluid 225 passages in the second level may extend in a second direction, the second direction being substantially perpendicular to and crossing the first direction.

In one or more embodiments, each of the first fluid passages 225 in the second level may extend under the first fluid passage 125 in the first level.

In one or more embodiments, the first fluid passages 225 in the second level may be interleaved with the second fluid passages 235 in the second level.

In FIG. 5, the inlet 105 and outlet 115 are shown as protruding (e.g., extending) from the first level 520 in a direction parallel to the flow direction of the fluid(s) through the flow manifold 500 (e.g., x-direction), but the present disclosure is not limited thereto. For example, the inlet 105 and/or the outlet 115 may protrude (e.g., extend) from the flow manifold 500 in a direction perpendicular to the flow direction of the fluids through the flow manifold 50 (e.g., the z-direction). Other suitable arrangements of the inlet 105 and/or the outlet 115 in the flow manifold 500 are contemplated, such an inlets and outlets extending at a 45° angle with respect to the flow direction of the fluid(s) through the flow manifold 500 or inlets and outlets protruding (e.g., extending) from the fluid(s) through the flow manifold 500 in the y-direction. In other embodiments, the inlets and the outlets may extend in different suitable directions from each other (e.g., the +x direction and the −x direction, and/or the like.). The inlets and outlets (e.g., the size, location, protruding direction, and/or the like. of the inlets and outlets) may be suitably varied to meet space requirements in a desired or suitable application (e.g., may be suitably designed to fit into a set or predetermined space). The inlet 105 and outlet 115 may each include a flange, threaded opening, barbed connection, welded joint, and/or the like, for fluid connection to a fluid handling system (e.g., an air conditioning system, a turbocharging system, and/or the like.).

In one or more of embodiments, the flow manifold may include a third level that includes a plurality of first fluid passages each in fluid communication with the first fluid passages 225 in the second level. The third level may include a plurality of second fluid passages each in fluid communication with the second fluid passages 235 in the second level. In one or more of embodiments, a number of the first fluid passages in the third level may be greater than a number of the first fluid passages 225 in the second level. Each of the first fluid passages 225 in the second level may be in fluid communication with the cool fluid inlet 105 and at least one of the first fluid passages in the third level. Each of the second fluid passages 235 in the second level may be in fluid communication with the warm fluid outlet 115 and at least one of the second fluid passages in the third level.

In one or more of embodiments, each of the second fluid passages in the third level may extend under each of the first fluid passages 225 in the second level.

In one or more of embodiments, the first fluid passages in the third level may extend in a first direction that may be substantially the same as the first direction of the first fluid passages 125 of the first level.

In one or more of embodiments, the flow manifold may include a fourth level that includes a plurality of first fluid passages each in fluid communication with the first fluid passages in the third level. The fourth level may include a plurality of second fluid passages each in fluid communication with the second fluid passages in the third level. In one or more of embodiments, a number of the first fluid passages in the fourth level may be greater than a number of the first fluid passages in the third level. Each of the first fluid passages in the third level may be in fluid communication with the cool fluid inlet 105 and at least one of the first fluid passages in the fourth level. Each of the second fluid passages in the third level may be in fluid communication with the warm fluid outlet 115 and at least one of the second fluid passages in the fourth level.

In one or more of embodiments, each of the second fluid passages in the fourth level may extend under each of the first fluid passages in the third level.

In one or more of embodiments, the first fluid passages in the fourth level may extend in a second direction that may be substantially the same as the second direction of the first fluid passages 225 of the second level.

The flow manifold in a cooling block according to the present disclosure may include only two hierarchical levels of fluid passages, each level configured to progressively partition or coalesce coolant flow. In some embodiments, the flow manifold may include at least three hierarchical levels of fluid passages.

### Flowthrough of Manifold/Microchannels

The flow manifold, across a plurality of levels (e.g., first level, second level, third level, and/or fourth level), separates a single inlet flow into a plurality of individual flows to better correspond to the microchannel array. Similarly, the flow manifold receives a plurality of individual fluid flows from the microchannel array, across the plurality of levels, and coalesces the fluids into a single outlet flow. For example, the first fluid passages act to direct (e.g., separate) one fluid flow emanating from the inlet, and the second fluid passages act to coalesce the other fluid flow for supply to the outlet. Each increasing level (first-second-third) may have smaller and/or more fluid passages to separate the inlet flow. Each decreasing level (third-second-first) may have larger and/or less fluid passages to coalesce the outlet fluid flow. The plurality of levels organizes and directs warm and cool fluid flows into and from the passages in the flow manifold. A fluid impermeable barrier (e.g., solid material), between adjacent warm and cool fluid passages prevents mixing of warm and cool fluids.

The interfacial arrangement of the fluid passages in the final (lowest) level of flow manifold may correspond to the microchannel array. For example, the fluid passages in the final (lowest) level may primarily extend substantially perpendicular to the extension direction of the microchannel array or, in contrast, substantially parallel to the extension direction of the microchannel array. The present disclosure, however, is not limited thereto. In other embodiments, the fluid passages in the final (lowest) level of flow manifold may extend at about a 45° angle with respect to the extension direction of the microchannel array. Further, the fluid passages in the final (lowest) level of flow manifold may have a length and/or width in a range of 0.1 millimeter (mm) to about 1 centimeter (cm) or, in some embodiments, a range of about 0.3 mm to about 5 mm.

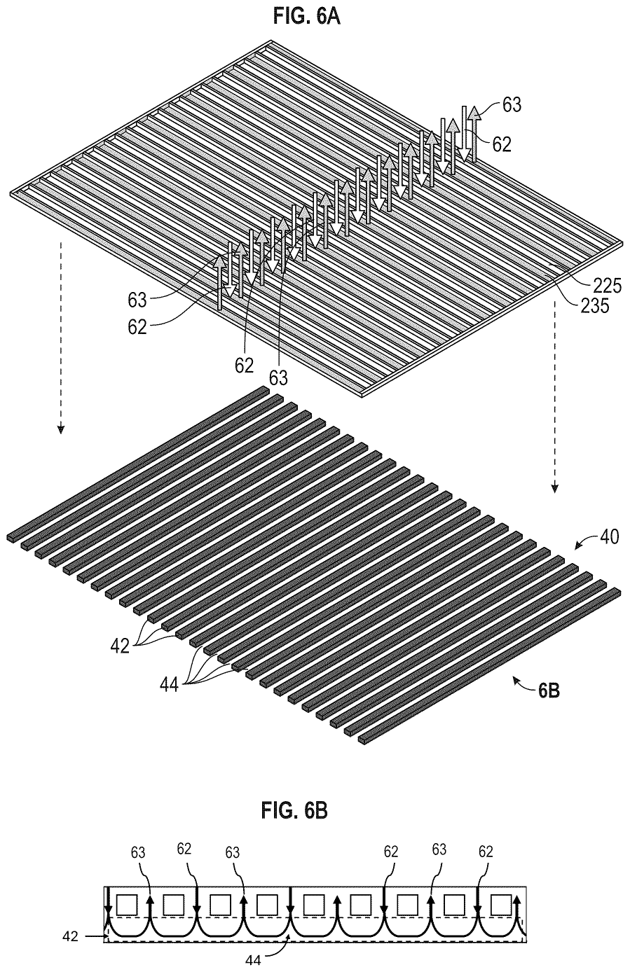

FIG. 6A shows fluid passages 225/235 in the second level 520 of flow 500 extending perpendicular to the extension direction of the microchannel array 40. For flow manifold 500 having only first and second levels 510/520, the first fluid passages 125 in first level 500 direct and separate fluid flowing from cool fluid inlet 105 into the first fluid passages 225 in second level 520, which is final (lowest) level. The downwardly pointing arrows represent cool fluid flows 62 in the first fluid passages 225, which are directed into the microchannel array 40 where two adjacent fins 42 separate a portion of the cool fluid in a first fluid passage 225 to form a single cool fluid flow 62 in a microchannel 44.

FIG. 6B is a cross sectional view of the interior of a microchannel 44 viewed from the perspective labeled “6B” in FIG. 6A. A lengthwise oriented fin 42 is shown in the background of FIG. 6B. Curved arrows show a typical flow path for cool fluid flows 62 entering a microchannel 44, absorbing heat, and exiting as warm fluid flows 63. The width of a microchannel 44 (distance between two adjacent fins 42) is limited to be at most about 200 μm and acts to confine a single cool fluid flow 62 to a relatively “short flow path” and forces it to reverse direction and travel out of the microchannel 44. In one or more embodiments, flow dividers may also be included within the manifold are shaped and spaced according to a Poiseuille distribution to ensure equal flow partitioning. Some dividers may be fanned to guide flow into multiple channels, while others may be parallel to reduce turbulence and maintain laminar flow throughout the manifold. The phrase “short flow path” as used herein, refers to the distance traveled by the coolant fluid in a fluid passage as described in more detail herein. Also, for example, the curved arrows in FIG. 6B illustrate the reversal of coolant flow within the microchannel 44, which enhances heat absorption and minimizes (reduces) thermal resistance.

As the direction of the cool fluid flows 62 is reversed, they absorb heat and transform into warm fluid flows 63, represented as upwardly pointing arrows in FIG. 6A, which are then directed out of the microchannel array 40 and into the second first fluid passages 235 of the second level 520. The heat may be absorbed from the base plate 30 and the fins 42 of the microchannel array 40. The second fluid passages 235 collect the warm fluid flows 63 directed out of the microchannel array 40 and the second fluid passages 135 in first level 510 coalesce the warm fluid flows into the warm fluid outlet 115.

### Additional Features

According to one or more embodiments of the present disclosure, the cooling block may include a compression gasket and the finned plate and the flow manifold may each have include a sealing groove. The dimensions of the sealing groove may be iteratively improved or optimized to provide sufficient sealing while also minimizing or reducing gasket compression-induced stresses, e.g., on the fins and/or the finned plate. The compression gasket may be an o-ring gasket and the sealing groove may be a recessed groove suitable for use with the o-ring gasket but the present disclosure is not limited thereto.

The compression gasket (e.g., o-ring gasket) may be or include rubber, silicone, other elastomeric materials, and/or a (e.g., any suitable) combination thereof. In some embodiments, the compression gasket may be a flat gasket or may be a formed-in-place gasket.

The finned plate may be coupled to the flow manifold with a bond interface such as a brazed bond, a soldered bond, an adhesive (e.g., epoxy) bond, a fusion bond, and/or a (e.g., any suitable) combination thereof. In one or more embodiments, the finned plate and the flow manifold may be fabricated as a single component and include a compression gasket and/or bond interface.

One or more aspects of embodiments of the present disclosure are directed toward a cooling system including at least one cooling block including a finned plate and a flow manifold as described herein, at least one pump, and at least one heat exchanger in fluid communication with the flow manifold of the cooling block.

One or more aspects of embodiments of the present disclosure are directed toward a cooling system including an electronic component, a cooling block as described herein on the electronic component, and a heat exchanger in fluid communication with the flow manifold of the cooling block. The electronic component may include a semiconductor chip and/or an integrated circuit but the present disclosure in not limited thereto.

One or more aspects of embodiments of the present disclosure are directed toward a systems-level integrated cooling system including a plurality of cooling blocks each as described herein, a shared coolant distributor configured to supply a coolant to each of the plurality of cooling blocks, a controller configured to monitor and adjust coolant flow rates to each of the plurality of cooling blocks based on thermal load, and a heat exchanger in fluid communication with the shared coolant distributor.

In one or more embodiments, each cooling block is configured as a modular unit that may be independently installed, monitored, and/or replaced within a larger thermal management system. This modularity supports scalable deployment in data centers, aerospace platforms, and other high-density electronics environments. The controller may receive input from temperature or flow sensors embedded in or near each cooling block and dynamically adjust flow rates using variable-speed pumps or electronically controlled valves. This enables real-time thermal load balancing and energy-efficient operation.

A coolant used in the cooling systems, cooling block, finned plate, and flow manifold of the present disclosure may be a single-phase coolant, a two-phase coolant, and/or a (e.g., any suitable) combination thereof. The coolant may include water, ethylene glycol, propylene glycol, oils, air, refrigerants, halocarbons, and/or one or more (e.g., any suitable) combination thereof.

In some embodiments, the coolant flowing in the cooling block, finned plate, and/or flow manifold and/or between the cooling block and the heat exchanger may have a laminar flow or a non-laminar flow.

In some embodiments, the pressure drop through the cooling block is sufficiently low that coolant may flow through the cooling block without being driven by a mechanical pump and/or if (e.g., when) driven by gravity alone. For example, gravity-driven flow may be needed temporarily (e.g. during a power disruption to the pump), but could be used long term with a large enough reservoir of coolant.

According to one or more embodiments of the present disclosure, a method of manufacturing a cooling block includes forming a flow manifold by stacking a plurality of layers, providing a finned plate that includes a microchannel array, and coupling the flow manifold and the finned plate, and an interior of the flow manifold is in fluid communication with the microchannel array.

In one or more embodiments the forming of the flow manifold may include stacking a plurality of layers of an injection molded material, stacking a plurality of layers of metal sheets, and/or a (e.g., any suitable) combination thereof.

In one or more embodiments the forming of the flow manifold may include stacking and bonding the plurality of layers, stacking and compressing the plurality of layers, and/or a (e.g., any suitable) combination thereof.

The following examples and experimental data are provided for illustrative purposes only, and do not limit the scope of one or more embodiments of the present disclosure.

### EXAMPLES

### Example 1

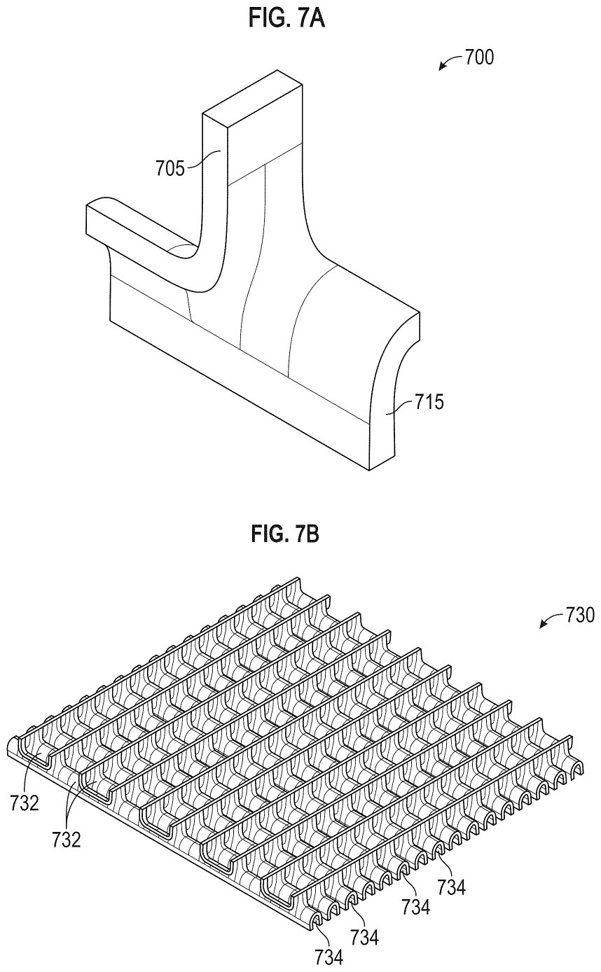

FIG. 7A shows a curvilinear transition layer unit (CTLU) cell 700 according to the present disclosure including top rail extrusion 705 and bottom rail extrusion 715, which are both completely vertically oriented and thus unsuitable for injection molding processes due to difficulties to remove these pieces from a mold, e.g., if (e.g., when) composed into an array layer. FIG. 7B shows a hierarchical-level transition (HLT) layer 730 that was created by mirroring and arraying the CTLU cell 700 and that provides an entire hierarchical level of the flow manifold of the present disclosure. The HLT layer 730 includes at least a portion of two hierarchical levels (e.g., first and second levels) of the flow manifold, having large structures 732 of the first level on the top and small structures 734 on the second level on the bottom. A flow manifold created by stacking additional hierarchical-level transition layers with larger and/or smaller structures would be difficult to remove from a mold, e.g., because of the length and number of rail type (kind) extrusions.

FIG. 7C, at right, shows a curvilinear transition layer unit (CTLU) cell 750 having a draft angle 760 according to the present disclosure. The draft angle 760 shown in FIG. 7C is about 5 degrees (9), but the present disclosure is not limited thereto.

FIG. 7D shows a longitudinally bisected curvilinear transition layer unit (CTLU) cell 770 including walls 772 and 774 and a draft angle of about 5 degrees on each into-the-mold extrusions. The longitudinally bisected CTLU cell 770 is a corner piece having walls 772 and 774 on two faces.

Here, FIGS. 7A to 7D collectively demonstrate how curvilinear and hierarchical geometries can be designed with draft angles suitable for injection molding, enabling scalable and cost-effective fabrication of complex flow manifolds.

### Example 2

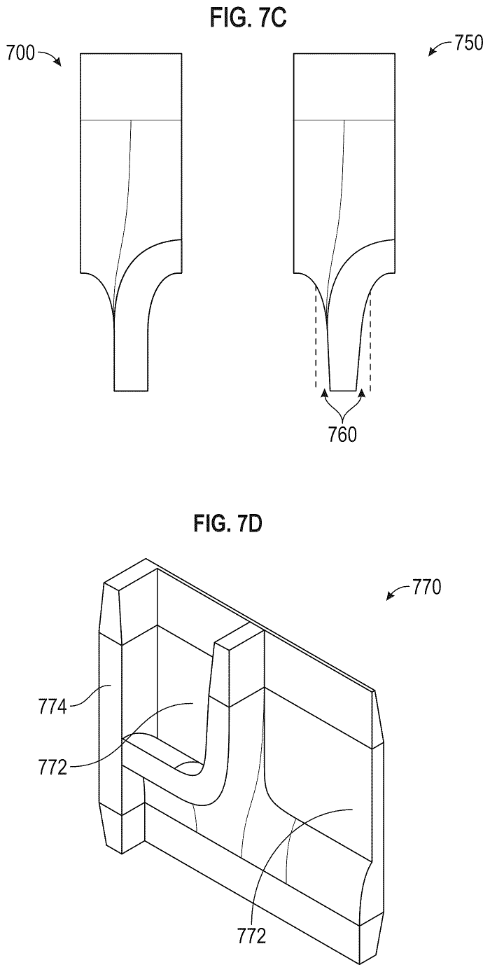

FIGS. 8-10 display the performance evaluation of a cooling block according to the present disclosure having at least 150 microchannels. The evaluations were conducted at 410 watts (W) with a maximum temperature difference between the flow manifold and the finned plate of 175° C. The results include short-throw guided circulation either within the microchannels or impinging the die directly, and a comparable cold plate not including the hierarchical interleaved flow routing of the present disclosure.

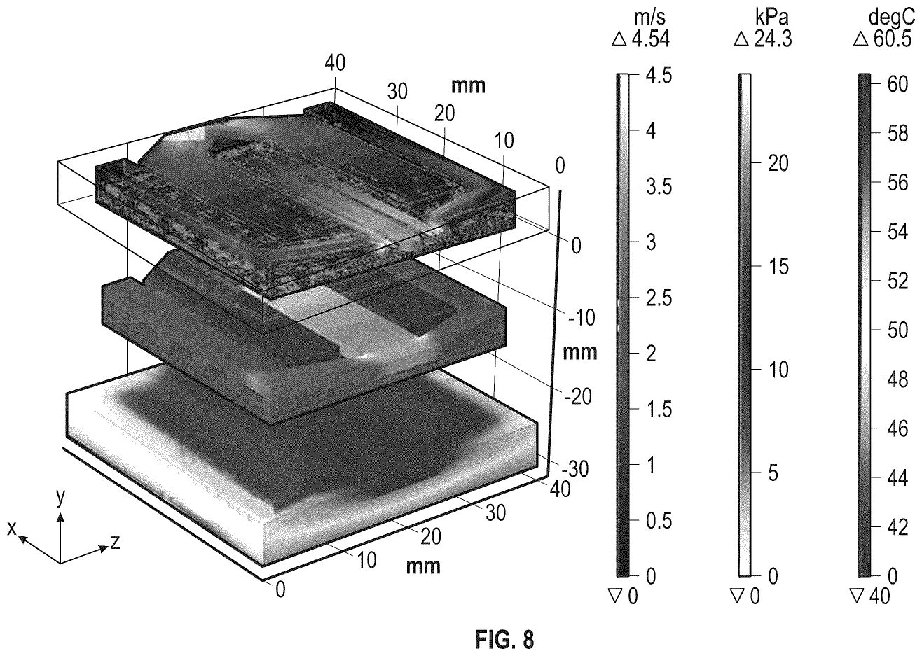

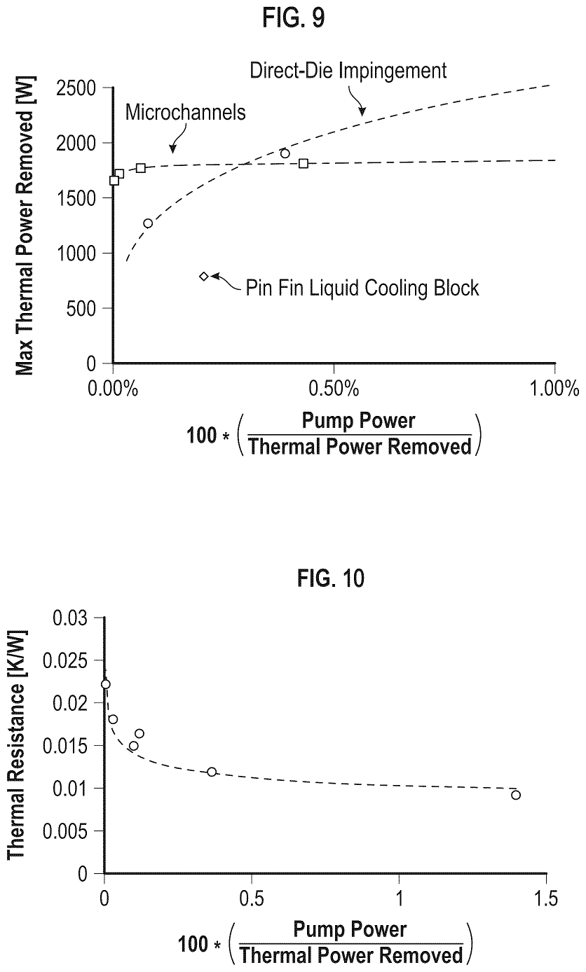

FIG. 8 includes flow streamlines, pressure distribution and temperature distribution. FIG. 9 shows thermal power removal measured against pump power. FIG. 10 shows thermal resistance measured against pump power.

Terms such as “substantially,” “about,” and “~” are utilized as terms of approximation and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or +30%, 20%, 10%, 5% of the stated value.

Numerical ranges disclosed herein include and are intended to disclose all subsumed sub-ranges of the same numerical precision. For example, a range of “1.0 to 10.0” includes all sub-ranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

While the present disclosure has been described in connection with certain example embodiments, it is to be understood that the present disclosure is not limited to the disclosed embodiments, but, on the contrary, is intended to cover one or more suitable modifications and equivalent arrangements included within the spirit and scope of the claims, and equivalents thereof.

The annotations used in FIGS. 1, 2 and 4A-7D are listed hereafter.

10: cooling block
20: finned plate
22: cover layer
23: inlet/outlet layers
24: first discretization layer
25: first crossflow layer
26: second discretization layer
27: second crossflow layer
28: third discretization layer
29: third crossflow layer
30: base plate
40: microchannel
42: fin
44: microchannel array
50: flow manifold
62: cool fluid flow
63: warm fluid flow
105: cool fluid inlet
115: warm fluid outlet
125: first fluid passages (first level)
135: second fluid passages (first level)
225: first fluid passages (second level)
235: second fluid passages (second level)
500: flow manifold
510: first level
520: second level
530: third level
700: curvilinear transition layer unit (CTLU) cell
705: top rail extrusion
715: bottom rail extrusion
730: hierarchical-level transition (HLT) layer
732: large structures
734: small structures
750: curvilinear transition layer unit (CTLU) cell
760: draft angle
770: longitudinally bisected curvilinear transition
layer unit (CTLU) cell
772: wall
774: wall

What is claimed is:

1. A cooling block comprising:
a finned plate comprising a base plate and a microchannel array; and
a flow manifold having stacked layers and comprising:
a first fluid passage open to an inlet and a second fluid passage open to an outlet in a first level of the flow manifold; and
first fluid passages and second fluid passages in a second level of the flow manifold,
each of the first fluid passages in the second level is in fluid communication with the inlet via the first fluid passage in first level, and
each of the second fluid passages in the second level is in fluid communication with the outlet via the second fluid passage in the first level.

2. The cooling block of claim 1, wherein the stacked layers comprise layers of an injection molded material comprising polymers, resins, metals, and combinations thereof.

3. The cooling block of claim 2, wherein the layers comprise curvilinear transition layer unit cells.

4. The cooling block of claim 3, wherein the curvilinear transition layer unit cells comprise a draft angle.

5. The cooling block of claim 1, wherein the stacked layers comprise layers of sheets.

6. The cooling block of claim 5, wherein the sheets comprise first metal sheets having a first set of physical properties and second metal sheets having a second set of physical properties.

7. The cooling block of claim 1, wherein the flow manifold comprises at least one inlet/outlet layer, at least one discretization layer, and at least one crossflow layer.

8. The cooling block of claim 7, wherein the flow manifold comprises at least one recessed layer.

9. The cooling block of claim 7, wherein the flow manifold comprises a microchannel layer and a baseplate layer.

10. The cooling block of claim 1, wherein
the first fluid passages in the second level are greater in number than the first fluid passages in the first level,
the first fluid passages in the first level extend in a first direction,
the first fluid passages in the second level extend in a second direction, the second direction perpendicular to and crossing the first direction,
each of the first fluid passages in the second level extend under the first fluid passages in the first level.

11. The cooling block of claim 1, wherein the first fluid passages in the second level are interleaved with the second fluid passages in the second level.

12. The cooling block of claim 1, wherein the microchannel array comprises a plurality of fins, the fins being connected to and extending from a surface of the base plate, adjacent ones of the fins being spaced apart from each other to form a plurality of microchannels between the fins, one of the microchannels being between each adjacent two of the fins, and
wherein an interior of the flow manifold is in fluid communication with the microchannels.

13. The cooling block of claim 12, wherein the microchannels extend in a direction parallel to each other and perpendicular to a direction of extension of a plurality of first fluid passages in a lowest level of the flow manifold.

14. The cooling block of claim 12, wherein a width of the microchannels is about 1 micrometer (μm) to about 1000 μm.

15. The cooling block of claim 12, wherein
the fins comprise a thermally conductive material and have a highest thermal conductivity axis with a conductivity of at least about 50 watt per meter degree K (W/m-K),
a thickness of the fins is about 1 μm to about 200 μm, and
a height of the fins is about 200 μm to about 3000 μm.

16. The cooling block of claim 1, wherein
the base plate comprises aluminum, carbon, copper, gold, molybdenum, nitrogen, palladium, platinum, silicon, silver, tungsten, graphite, diamond, an alloy thereof, a compound thereof, and any suitable combination thereof,
a thickness of the base plate is about 10 μm to about 5000 μm, and
a shear modulus of the base plate is about 10 megapascal (MPa) to about 300 gigapascal (GPa).

17. The cooling block of claim 1, wherein the flow manifold comprises a thermal isolation layer between the inlet and the outlet, the thermal isolation layer comprising a gas-filled cavity, an aerogel, or a low-conductivity polymer.

18. A cooling system comprising:
an electronic component;
a cooling block according to claim 1 on the electronic component; and
a heat exchanger in fluid communication with the flow manifold of the cooling block.

19. The cooling system according to claim 18, wherein the cooling system comprises:
a plurality of cooling blocks;
a shared coolant distributor configured to supply a coolant to each of the plurality of cooling blocks;
a controller configured to monitor and adjust coolant flow rates to each of the plurality of cooling blocks based on thermal load; and
the heat exchanger in fluid communication with the shared coolant distributor.

20. A method comprising:
forming a flow manifold by stacking a plurality of layers;
providing a finned plate comprising a microchannel array;
coupling the flow manifold and the finned plate,
wherein,
an interior of the flow manifold is in fluid communication with the microchannel array, and
the method is a method of manufacturing a cooling block.

21. The method of claim 20, wherein the forming of the flow manifold comprises:
stacking a plurality of layers of an injection molded material,
stacking a plurality of layers of sheets, or
combinations thereof.
